(19) United States
(12) Patent Application Publication
(10) Pub. No.: US 2007/0125304 A1
(43) Pub. Date: Jun. 7, 2007

(54) TRANSPORT ROLLERS

(75) Inventor: Klaus Hartig, Avoca, WI (US)

Correspondence Address: INTELLECTUAL PROPERTY GROUP;FREDRIKSON & BYRON, P.A., 200 SOUTH SIXTH STREET, SUITE 4000, MINNEAPOLIS, MN, 55402, US

(73) Assignee: Cardinal CG Company, Eden Prairie, MN (US)

(21) Appl. No.: 11/553,083

(22) Filed: Oct. 26, 2006

Related U.S. Application Data
(60) Provisional application No. 60/741,120, filed on Dec. 1, 2005.

(51) Int. Cl. C23C 16/00; C23C 14/00

(52) U.S. Cl. 118/729; 427/294; 118/50

(57) ABSTRACT

A nonstick transport roller is provided, the roller having an outer surface defined by a thickness of nonstick material. A rope can optionally be wound around the outer surface of the roller to define an elevated support for engaging a major substrate surface. A vacuum deposition chamber for applying thin films onto substrates is also provided, the chamber having a cavity in which a controlled vacuous environment can be established, the chamber including a series of transport rollers, at least one of the transport rollers comprising a cylindrical tube having an outer surface defined by a thickness of nonstick material, optionally with a rope wound around the tube to define an elevated support for engaging a bottom major surface of a substrate.

### CROSS-REFERENCE TO RELATED APPLICATIONS

The present application claims priority to U.S. application No. 60/741,120, filed Dec. 1, 2005, the disclosure of which is incorporated herein by reference.

### FIELD OF THE INVENTION

The present invention relates generally to transport rollers. More particularly, the invention relates to transport rollers having non-stick surfaces.

### BACKGROUND OF THE INVENTION

Transport rollers are commonly used to convey substrates and other materials through film deposition chambers. For example, vacuum deposition chambers, e.g., sputtering, chambers, commonly employ transport rollers for conveying glass and other substrates through the chambers as material is being deposited onto the substrates. During sputtering, a controlled (e.g., vacuous) environment is established inside a sputtering chamber. At least one sputtering target comprising sputterable material is positioned in the chamber. A power supply is operatively connected to the target to apply an electric (e.g., cathodic) charge to at least a portion of the target. Commonly, a relatively positively charged anode is positioned in the chamber proximate the target. The chamber is evacuated and then a low-pressure gaseous atmosphere is delivered to the chamber. The electrodes are energized to establish a plasma in the chamber. Charged ions (e.g., positively-charged ions) from the plasma bombard the target, causing particles of target material to be emitted from the target. While most of these particles are deposited upon the substrate in the chamber, a significant amount of sputtered material (commonly about 5-10% of the total sputtered material) is deposited upon interior surfaces of the chamber, such as transport rollers, interior chamber walls, shields, end blocks, anodes and/or gas-delivery pipes.

In many sputtering chambers, the targets are only placed above the path of substrate travel, so that target material is only sputtered generally downwardly. Transport rollers are placed along the path of substrate travel and substrates are positioned on the transport rollers so as to leave gaps between adjacent substrates. Since the substrates rest on top of the rollers, they tend to shield the rollers from being coated with much of the downwardly sputtered material. However, a relatively small amount of sputtered material passes through the gaps and lands on the rollers.

In certain particularly advantageous sputtering chambers, one or more targets are placed below the path of substrate travel, so that target material is sputtered generally upwardly. Sputtering chambers of this nature are described in U.S. patent applications Ser. Nos. 09/868,542, 09/868,543, 09/979,314, 09/572,766 and 09/599,301, the entire contents of each of which are herein incorporated by reference. In these chambers, the upwardly sputtered material preferably passes between the spaced-apart transport rollers and onto the bottom surface of the substrates. Since the substrates rest on top of the rollers, they do not shield the rollers from being coated by the upwardly sputtered material. As a result, the transport rollers are exposed more continuously to sputtered material. Thus, the buildup of coating on transport rollers in upward sputtering chambers is more rapid than in conventional downward sputtering chambers. In certain modes of coating operation, no substrates are present during sputtering. This commonly occurs while the sputtering process is being adjusted or conditioned. During such times, the transport rollers can be coated by a thick layer of sputtered material.

The overcoating of transport rollers can pose significant problems. For example, it necessitates periodic removal of coating from the rollers and/or replacement of badly coated rollers. In some cases, transport rollers are provided with ropes wound about the rollers, which define the surfaces upon which substrates are supported during conveyance. Coating may also build up on these ropes. This too may necessitate periodic removal of coating from the ropes and/or replacement of badly coated ropes. Contamination removal and replacement of rollers and/or roller parts can be difficult, time consuming, and it can significantly reduce production capabilities.

In unusual cases, the build-up of coating on transport rollers may even cause substrates conveyed over the rollers to shift their orientation on the rollers as they are conveyed. For example, when transport rollers are provided with ropes that are wound about the rollers, the surfaces of these ropes are sometimes coated unevenly. As a result, the substrates during conveyance may tend to shift somewhat (i.e., in terms of their orientation on the rollers). This is undesirable in that it may cause a substrate to fall off of the transport rollers or cause a log jam in the coater, potentially resulting in substrate breakage.

Thus, in sputtering chambers and other deposition chambers where materials are deposited, the exposed parts of each transport roller are vulnerable to being coated. This is particularly true in chambers where materials are sputtered upwardly between transport rollers. Therefore, it would be desirable to provide a transport roller and/or transport roller parts that are resistant to becoming coated with the deposited materials.

### SUMMARY OF THE INVENTION

A transport roller for conveying a large-area substrate is provided. The roller comprises a cylindrical body having an outer surface defined by a thickness of nonstick material. An elevated support, e.g., a wound rope, is provided about the cylindrical body for engaging a bottom major surface of the large area substrate. In preferred embodiments, the thickness of nonstick material is formed by a nonstick coating, e.g., a nonstick coating of polytetrafluoroethylene. The cylindrical body of the roller preferably comprises a hollow tube. The hollow tube is preferably aluminum. In certain embodiments, the rope wound around the cylindrical body also has a thickness of nonstick material, e.g., polytetrafluoroethylene. Also, the wound rope preferably comprises a central core formed of a different material than the nonstick material defining the outer surface of the rope. For example, the central core of the rope can be comprised of an inner wire, e.g., a steel wire. The elevated support can also be a belt wound around at least part of a transport roller and at least part of a guide roller or other transport roller. The transport roller preferably has a length of at least about 0.5 meter, more preferably of at least about 1 meter, and optimally between about 2 meters and about 4 meters.

A vacuum deposition chamber for applying thin films onto a substrate is also provided. The chamber has a cavity in which a controlled environment can be established. The chamber includes a series of transport rollers and at least one of the transport rollers comprise a cylindrical body having an outer surface defined by a thickness of nonstick material. An elevated support, e.g., a wound rope, is provided about the cylindrical body for engaging a bottom major surface of the large area substrate. The transport rollers are preferably spaced apart along a path of substrate travel extending through the cavity. The transport rollers are also preferably arranged so that the wound ropes of respective adjacent transport rollers are wound in alternating directions. In certain embodiments, the wound rope also has a thickness of nonstick material, e.g., polytetrafluoroethylene. Also, the wound rope preferably comprises a central core formed of a different material than the nonstick material defining the outer surface of the rope. For example, the central core of the rope can be comprised of an inner wire, e.g., a steel wire.

In preferred embodiments, the chamber includes at least one sputtering target positioned in the cavity. The target is operatively connected to a power supply adapted to apply an electric charge to at least a portion of the target. In certain embodiments, the chamber is an upward coating apparatus adapted for coating the bottom major surface of the substrate when the substrate is conveyed through the chamber over the rollers. Preferably, the upward coating apparatus is a sputtering chamber and comprises at least one lower sputtering target mounted in the cavity below the transport rollers. In other embodiments, the chamber is a dual direction coating apparatus adapted for simultaneously coating the bottom major surface of the substrate and a top major surface of the substrate when the substrate is conveyed through the chamber over the transport rollers. Preferably, the dual direction coating apparatus is a dual direction sputtering chamber with at least one upper sputtering target mounted in the cavity above the transport rollers and at least one lower sputtering target mounted in the cavity below the transport rollers.

A method of conveying a substrate is also provided. The method comprises providing a vacuum deposition chamber for applying thin films onto the substrate and transporting the substrate through the vacuum chamber. The chamber has a cavity in which a controlled environment can be established and includes a series of transport rollers. At least one of the transport rollers comprises a cylindrical body having an outer surface defined by a thickness of nonstick material. An elevated support, e.g., a wound rope, is provided about the cylindrical body for engaging a bottom major surface of the large area substrate. Preferably, when the substrate is conveyed over the transport rollers, the bottom major surface comes into direct contact with the rope but without directly contacting the outer surface of the cylindrical body. In certain embodiments, the wound rope also has a thickness of nonstick material, e.g., polytetrafluoroethylene. Preferably, the bottom major surface of the substrate comes into direct contact with the nonstick material of the rope during the conveying the substrate over the transport rollers. Also, the wound rope preferably comprises a central core formed of a different material than the nonstick material defining the outer surface of the rope. For example, the central core of the rope can be comprised of an inner wire, e.g., a steel wire.

### BRIEF DESCRIPTION OF THE DRAWINGS

FIG. 1a illustrates a perspective view of a roller according to an embodiment of the invention;

FIG. 1b illustrates a perspective view of a roller according to another embodiment of the invention;

FIG. 1c illustrates a perspective view of a roller according to another embodiment of the invention;

FIG. 1d illustrates a perspective view of a roller according to another embodiment of the invention;

FIG. 2a illustrates a cross-sectional view of a rope according to an embodiment of the invention;

FIG. 2b illustrates a cross-sectional view of a rope according to another embodiment of the invention;

FIG. 2c illustrates a cross-sectional view of a rope according to another embodiment of the invention;

FIG. 2d illustrates a cross-sectional view of a rope according to another embodiment of the invention;

FIG. 3 illustrates a schematic cross-sectional view of a series of transport rollers according to an embodiment of the invention;

FIGS. 4a and 4b illustrate a schematic cross-sectional view of a series of transport rollers according to certain embodiments of the invention;

FIG. 5 illustrates a schematic end view of a downward sputtering chamber employing rollers of the invention;

FIG. 6 illustrates a schematic end view of an upward sputtering chamber employing rollers of the invention;

FIG. 7 illustrates a schematic end view of a dual-direction sputtering chamber employing rollers of the invention;

FIG. 8 illustrates a schematic top view of a series of transport rollers mounted in a deposition chamber according to one embodiment of the invention; and

FIG. 9 illustrates a schematic top view of a series of transport rollers mounted in a deposition chamber according to another embodiment of the invention.

### DETAILED DESCRIPTION OF THE PREFERRED EMBODIMENTS

The following detailed description is to be read with reference to the drawings, in which like elements in different drawings have been given like reference numerals. The drawings, which are not necessarily to scale, depict selected embodiments and are not intended to limit the scope of the invention. Skilled artisans will recognize that the examples given have many useful alternatives that fall within the scope of the invention.

The present invention provides a transport roller having a nonstick surface. The transport roller can be employed for transporting substrates through a variety of deposition chambers. The nonstick surface is provided to reduce the build-up of coating material on the surface of the roller. Transport rollers of the invention are desirable for use in vacuum deposition chambers, especially in large-area deposition chambers. The rollers are particularly desirable for use in deposition chambers adapted for carrying out upward deposition processes. Further, the rollers can be used to particular advantage in sputtering chambers, especially those having lower targets configured for upward sputtering.

In certain embodiments, the invention provides a transport roller comprising a roller body having an outer surface defined by a thickness of nonstick material. Preferably, one or more elevated supports, e.g., ropes are wound around the roller body and define an elevated support for engaging a major surface of a substrate. When the substrate is conveyed over the roller, the bottom surface of the substrate comes into direct contact with, and is supported by, the one or more ropes, rather than the surface of the roller's body. Suitable ropes can be obtained from General Plasma, Inc. (Tucson, Ariz. USA).

The roller's body has an outer surface defined by a thickness of nonstick material. In some embodiments, this thickness of nonstick material is formed by a coating of one or more nonstick materials. For example, a coating of nonstick material can be applied over the roller body. In one embodiment, the roller body is fabricated from a metallic (i.e., a metal or metal alloy) material and a nonstick outer coating is applied over at least a portion of the outer surface of this metallic roller body. For example, in some cases, nonstick spray can be sprayed onto the outer surface. In certain cases, the roller body is formed of a vacuum friendly metal, such as aluminum metal. The roller body can be provided in any suitable configuration, such as a cylindrical tube. Alternatively, the entire roller, including the outer surface of the roller, can be formed of a nonstick material. As another alternative, the roller body can be manufactured (e.g., cast) in such a way that an inner thickness of the roller's body is a metallic material while an outer surface is a non-metallic non-stick material.

Any suitable nonstick material can be provided on the outer surface of the roller. If the roller is to be used in a vacuum deposition chamber, the nonstick material is preferably a vacuum friendly material. In certain embodiments, the nonstick material is polytetrafluoroethylene. Polytetrafluoroethylene is commercially available under the brand name Teflon® from Dupont, headquarters in (Wilmington, Del. USA). Other suitable nonstick materials include, but are not limited to, graphite, ceramic, and molybdenum disulphide. The coating of nonstick material can be deposited over the exterior side of the roller body by plasma spraying or paint spraying. For example, Teflon® can be sprayed onto the exterior of the roller. In some embodiments, a sheet of nonstick material can be provided, e.g., a Teflon® sheet, and then wrapped over the roller body. In some embodiments, rings of nonstick material (e.g., carbon or graphite rings) are provided and then mounted on the roller body.

In certain embodiments, the roller body is a cylindrical body. In preferred embodiments, the roller comprises a cylindrical tube. Cylindrical tubes of this nature can be obtained from a variety of well-known commercial sources, such as General Plasma, Inc. (Tucson, Ariz. USA), Leybold Vakuum GmbH (Cologne, Germany), Bekaert Technologies, Inc. VDS NV (Deinze, Belgium), and BOC Coating Technology (Fairfield, Calif. USA). The cylindrical tube can be a hollow tube or a solid tube.

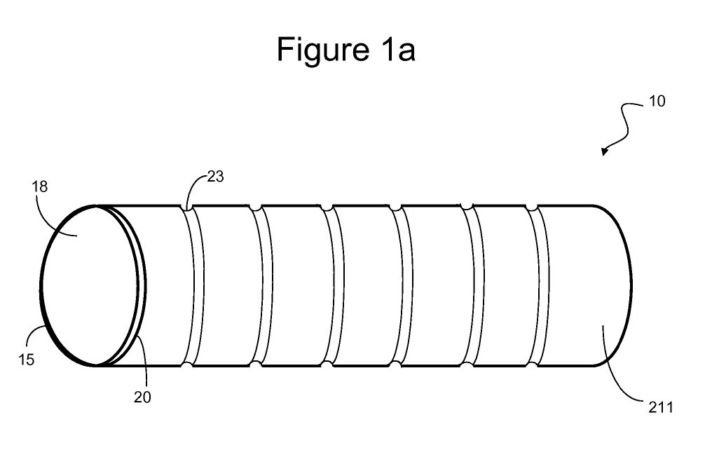

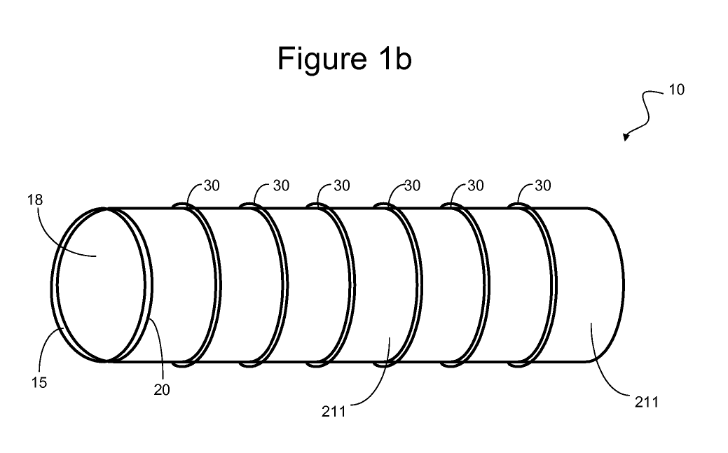

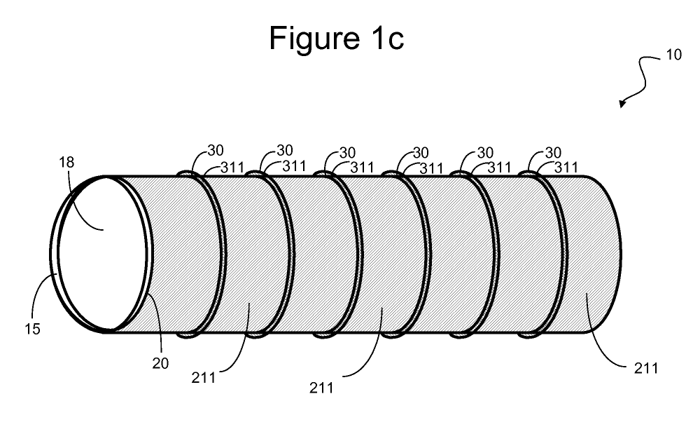

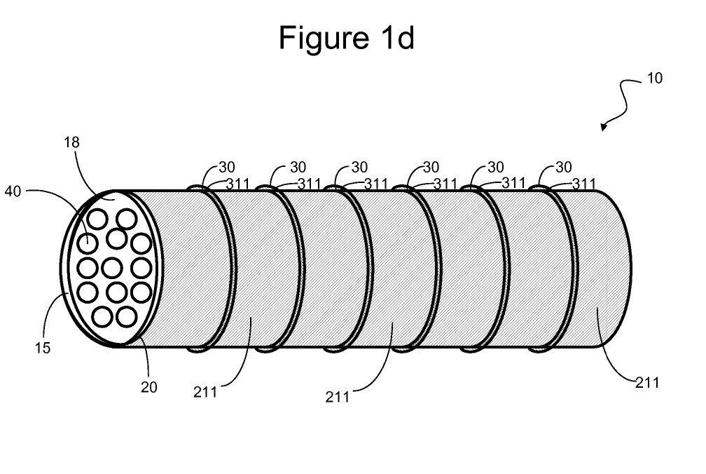

FIG. 1a illustrates a perspective view of a transport roller 10 according to an embodiment of the invention. The roller comprises a cylindrical body. Here, the cylindrical body comprises a hollow cylindrical tube 15 bounding a central cavity 18. The tube 15 has an outer surface 20 defined by a thickness of nonstick material 211. As noted above, the thickness of nonstick material 211 may be a coating of nonstick material on the surface of the roller, or the entire roller may be formed of nonstick material, or only an outer thickness of the wall of the roller may be formed by nonstick material (other than a coating), etc. In the illustrated embodiment, the tube 15 is made entirely of a nonstick material so that the outer surface 20 is defined by the nonstick material 211. The tube includes one or more grooves 23 which receive and hold in place a rope, spiral spring or other elevated support. The grooves 23 are optional and need not be provided in all cases.

In FIG. 1b, a rope 30 is wound around the tube 15. The rope 30 defines an elevated support for engaging (e.g., supporting) a bottom major surface of each substrate conveyed over the roller. The illustrated rope 30 is wound spirally about the tube. In other embodiments, a plurality of annular ropes (e.g., spaced apart along a length of the cylindrical body) are provided around each roller. The rope(s) may or may not have an outer surface defined by a thickness of nonstick material. When provided, a thickness of nonstick material defining an outer surface of the rope can be an outer coating, or the entire rope can be formed of a nonstick material so that the outer surface is defined by the nonstick material. In the embodiment of FIG. 1b, the rope is not provided with a thickness of nonstick material that defines the outer surface of the rope.

In some embodiments, an elevated support other than a rope is provided about the roller. For example, the elevated support can be a series of bumps, rings or any other support structure which supports a substrate during conveyance without the substrate being in direct contact with the roller body. A spiral spring can also be placed around a roller body to provide support to the substrate. Rather, the substrate is in direct contact with the elevated support as it is conveyed along the path of substrate travel. In certain embodiments, the elevated support structure has an outer surface defined by a thickness of nonstick material. The thickness of nonstick material on the elevated support may be a coating of nonstick material on the surface of the structure, or the entire structure may be formed of nonstick material, or only an outer thickness of the structure may be formed by nonstick material (other than a coating).

Figure c illustrates a perspective view of a transport roller according to another embodiment of the invention. The roller comprises a cylindrical body. Here again, the cylindrical body comprises a hollow cylindrical tube 15 bounding a central cavity 18. The tube 15 again has an outer surface 20 that is defined by a thickness of nonstick material 211. This thickness of nonstick material 211 can optionally comprise a nonstick coating applied to the surface 20 of the tube 15. The tube 15 can optionally be fabricated of aluminum metal over which a coating 20 of a nonstick material, e.g., polytetrafluoroethylene, has been applied. A rope 30 is also spirally wound around the illustrated tube 15. As noted above, the rope 30 serves as an elevated support for engaging the bottom of a substrate. In the embodiment of FIG. 1c, the rope is provided with an outer surface defined by a thickness of nonstick material. This thickness of nonstick material 311 can optionally be formed by an outer coating of nonstick material.

FIG. 1d illustrates a perspective view of a transport roller according to another embodiment of the invention. In FIG. 1d, the illustrated roller comprises a cylindrical tube bounding a central cavity 18 in which one or more venting holes 40 are disposed at each end of the roller. In this embodiment, the rope 30 has an outer surface defined by nonstick material 311, which can optionally be a coating.

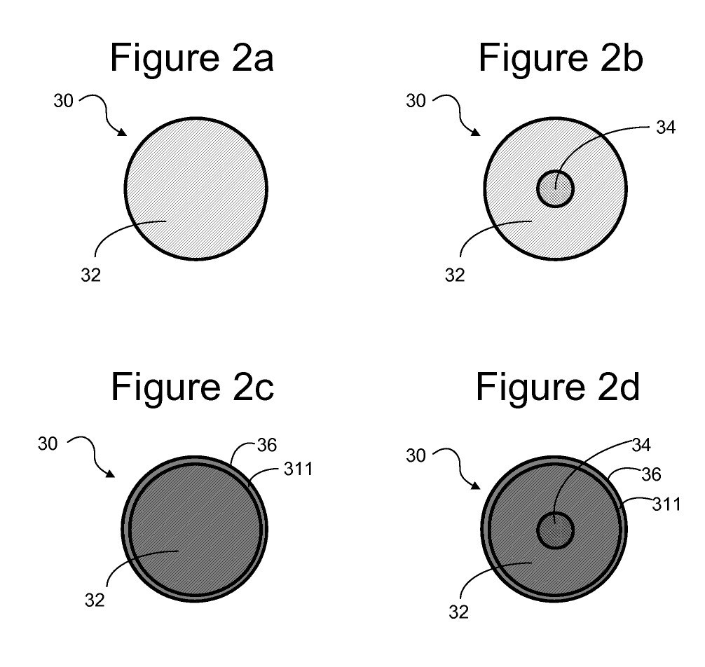

Different types of a rope are used in different embodiments. FIG. 2a illustrates a cross-sectional view of a rope 30 wherein the entire rope is formed of a single rope material 32. A rope of this nature may be provided, for example, in embodiments like that depicted in FIG. 1a. The rope material 32 is preferably a vacuum friendly material. For example, the rope material 32 can be a carbon fiber material. A suitable carbon fiber material is sold commercially from Dupont, under the trade name Kevlar®.

FIG. 2b illustrates a cross-sectional view of a rope 30 comprising a central core 34. Preferably, the central core 34 is formed of a different material than the outer thickness 32 of the rope. In some cases, the central core 34 can comprise (e.g., be) an inner wire. The inner wire, when provided, can advantageously be a metal wire, e.g., an aluminum wire. A rope having a durable central core, e.g., an inner metal wire, can be advantageous in helping to prevent damaged ropes from unraveling or otherwise falling from a roller. When conveying substrates over a rope-bearing roller, the substrates come into direct contact with the rope(s). During conveyance of glass sheets, for instance, sharp edges of the glass may bump into the rope and slash it. When a rope is slashed completely (i.e., when a slash extends through the entire cross-section of the rope), it may unravel from the roller in some cases. The unraveling may cause substrates to become damaged. In any event, an unraveled rope needs to be replaced, which requires costly processing downtime.

FIG. 2c illustrates a cross-sectional view of a rope 30 having an outer surface defined by a thickness (optionally a coating) of nonstick material. The rope material 32 preferably comprises a vacuum friendly material such as Kevlar®. The nonstick material can optionally be polytetrafluoroethylene. Of course, the nonstick material can also be coatings of graphite, ceramic, or molybdenum disulphide.

FIG. 2d illustrates a cross-sectional view of a rope comprising a central core 34, an intermediate thickness 32 of rope material, and an outer thickness of nonstick material. The rope of FIG. 2d includes the features of the rope shown in FIG. 2c, and further includes a central core 34. The central core 34 can optionally be a metal wire, e.g., an aluminum wire.

In some embodiments, the invention provides transport rollers that are adapted for transporting large-area substrates. Preferably, each such transport roller is adapted to accommodate large-area substrates having a width of at least about 0.5 meter, perhaps preferably at least about 1 meter, perhaps more preferably at least about 1.5 meters, e.g., between about 2 meters and about 4 meters, and in some cases at least about 3 meters. The length of each transport roller preferably is within one or more of these ranges.

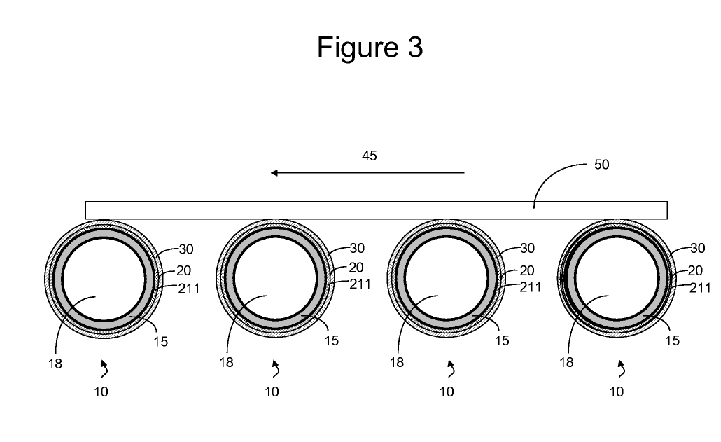

FIG. 3 illustrates a cross-sectional view of a series of transport rollers 10 over which a substrate 45 is being conveyed. Each of the illustrated rollers 10 comprises a tube 15 bounding a central cavity 18. The outer surface 20 of the tube is defined by a thickness of nonstick material 211, optionally a nonstick coating. A rope 30 is wound around each of the tubes 15. The rope about each tube provides an elevated support for substrates. As shown in FIG. 3, during conveyance of a substrate over the rollers 10, the substrate 45 rests on the elevated rope 30, as opposed to on the nonstick roller surface 20. Thus, the substrate is supported by, and is in direct contact with, the elevated ropes 30 as it is conveyed along the path of substrate travel 45.

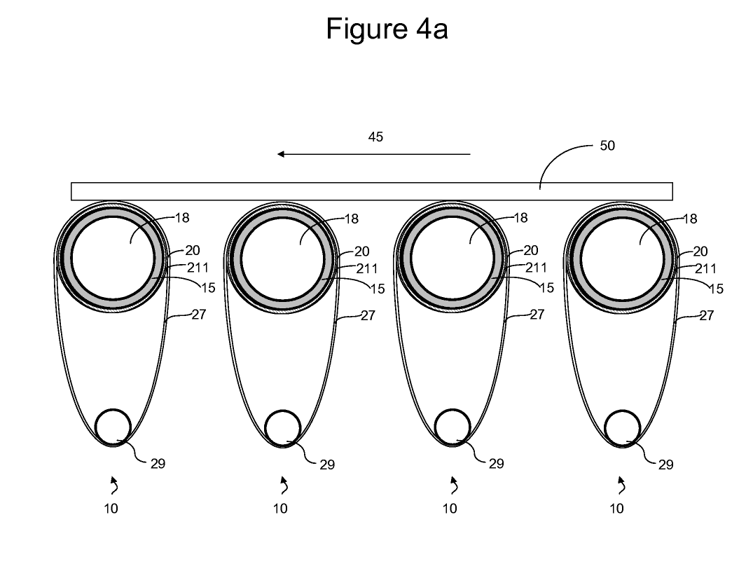

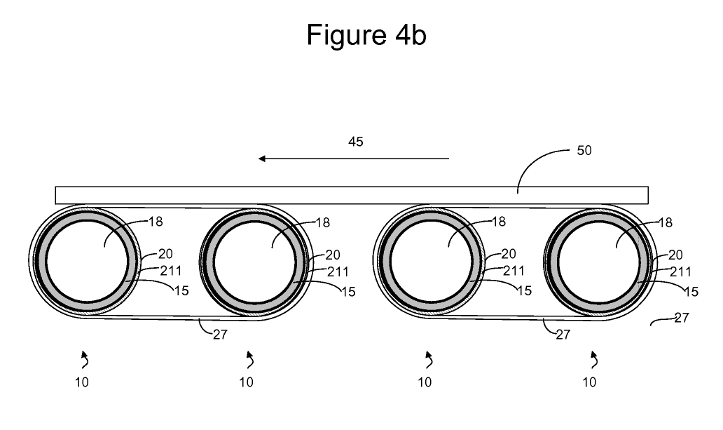

In some embodiments, belts are wound around the transport rollers and serve as supports for the substrates. FIG. 4a illustrates a transport roller according to an embodiment wherein a belt 27 is wound around the outer surface 20 of each transport roller and another guide roller 29 which is not part of the transport roller. The guide roller 29 is preferably also a roller which moves in either a clockwise or counterclockwise motion. Preferably, each the transport roller 10 and the corresponding guide rollers 29 move in a similar direction so that the belt moves over the transport roller in a continuous motion. The transport roller in this embodiment preferably also has an outer surface formed of nonstick material 15. The substrate rests directly on top of the belt 27 as opposed to on top of the nonstick outer surface of the transport roller. In some cases, the belt surface in contact with the substrate can also have a nonstick surface, although this is not required.

FIG. 4b illustrates another embodiment wherein a substrate is supported by a belt wound about a transport roller. In these embodiments, a belt 27 is wound around two or more transport rollers as opposed to being wound around one transport roller and a supplemental structure such as a guide roller, as in FIG. 4a. In FIG. 4b, the belt 27 is wound around two transport rollers. However, the belt 27 can also be wound around three, four, or any desirable number of transport rollers. Again, the belt 27 serves as a substrate support and is in direct contact with the substrate.

The present invention also provides a vacuum deposition chamber employing at least one transport roller of the invention. Preferably, the chamber includes a plurality of transport rollers of the invention. For example, all, substantially all, or a majority of the transport rollers in the present chamber can be rollers of the invention. The transport roller(s) in the present chamber can reflect the features of any of the embodiments described in the present disclosure. The deposition chamber can be adapted for carrying out upward and/or downward vacuum deposition processes. In certain preferred embodiments, the chamber is adapted for carrying out an upward deposition process. The chamber has a cavity in which a controlled (e.g., vacuous) environment can be established. In certain embodiments, the cavity contains a gaseous atmosphere at a pressure of less than about 140 torr., and perhaps more preferably less than about 0.1 torr. In one embodiment, the pressure is between about 1 mtorr. and about 0.1 torr, perhaps more preferably between about 1 mtorr. and about 30 mtorr. In some embodiments, the vacuum deposition chamber is a sputtering chamber. Sputtering chambers are well known in the art and the invention extends to any sputtering chamber that is provided with one or more transport rollers of the invention.

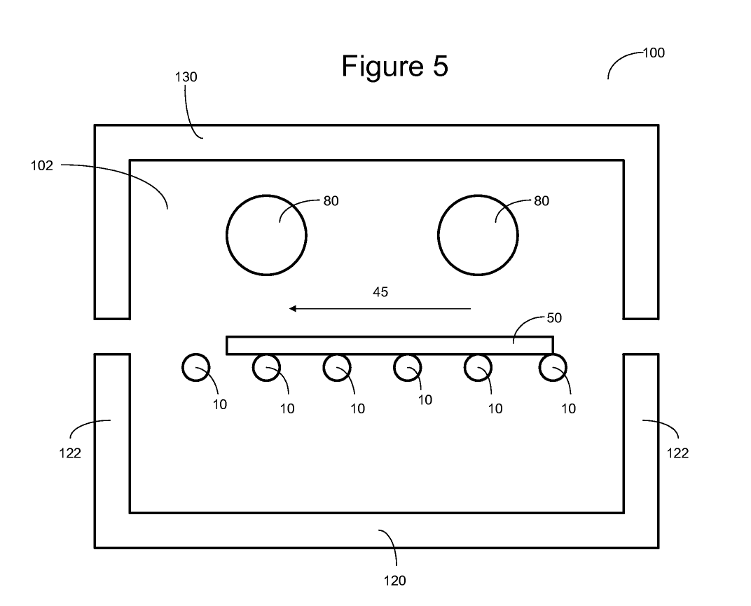

In certain embodiments, the vacuum deposition chamber is a downward sputtering chamber. Downward sputtering chambers are well known in the art. Useful downward sputtering chambers are described in U.S. Pat. No. 4,166,018 (Chapin), the entire teachings of which are incorporated herein by reference. FIG. 5 illustrates a schematic end view of a downward sputtering chamber 100 employing transport rollers 10 of the invention. The rollers can be provided in any of inventive forms described above. Here, the illustrated substrate 50 is resting directly on one or more ropes about each roller, although the rope(s) is/are not depicted here. The sputtering chamber 100 includes a base (or “floor”) 120, a plurality of side walls 122, and a ceiling (or “top lid” or “cover”) 130, together bounding a sputtering cavity 102. One or more upper targets 80 are mounted above the path of substrate travel 45. In FIG. 5, two upper targets are provided, although this is by no means required. For example, a single upper target could alternatively be used. Moreover, the chamber can include one or more planar targets, even though cylindrical targets are shown.

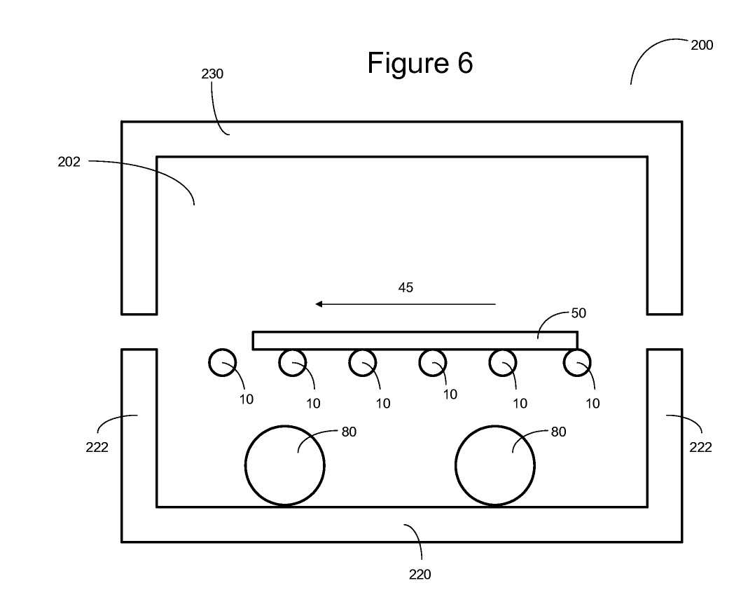

In certain preferred embodiments, the vacuum deposition chamber is an upward sputtering chamber. Particularly useful upward sputtering chambers are described in U.S. patent applications Ser. Nos. 09/868,542, 09/868,543, 09/979,314, 09/572,766, and 09/599,301, the entire contents of each of which are incorporated herein by reference. FIG. 6 illustrates a schematic end view of an upward sputtering chamber 200 employing transport rollers 10 of the invention. The illustrated rollers are provided in one or more of the invention forms described above. Here, the illustrated substrate 50 is resting directly on one or more ropes about each roller, although the rope(s) is/are not depicted here. The sputtering chamber 200 includes a base (or “floor”) 220, a plurality of side walls 222, and a ceiling 230, together bounding the sputtering cavity 202. One or more lower targets 180 are mounted below the path of substrate travel 45. In the illustrated embodiments, two lower targets are provided, even though this is not required. For example, a single lower target could alternatively be used. Moreover, the chamber can include one or more planar targets, although cylindrical targets are shown.

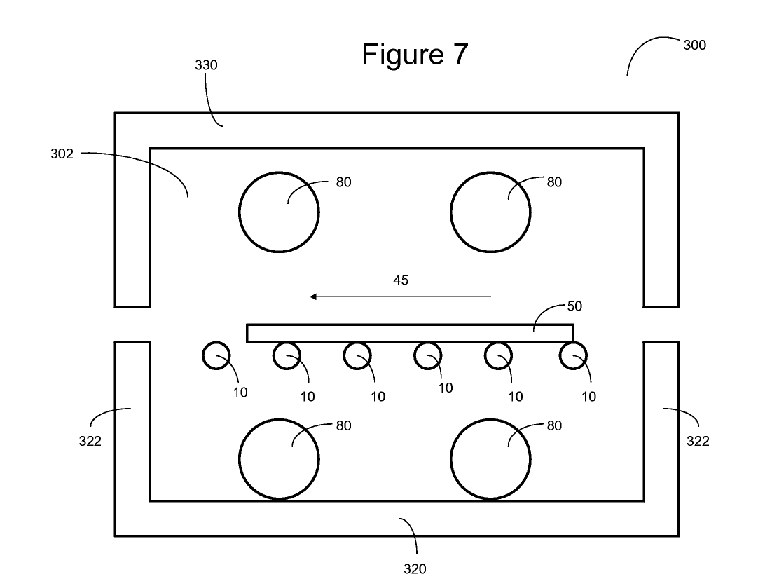

In certain embodiments, the vacuum deposition chamber is a dual direction sputtering chamber. Particularly useful dual direction sputtering chambers are described in U.S. patent applications Ser. Nos. 09/868,542, 09/868,543, 09/979,314, 09/572,766, and 09/599,301, the entire contents of each of which are incorporated herein by reference. FIG. 7 illustrates a schematic end view of a dual direction sputtering chamber 300 employing transport rollers 10 of the invention. The rollers can be provided in any of the inventive forms previously described. Here, the illustrated substrate 50 is resting directly on one or more ropes about each roller, although the rope(s) is/are not depicted here. The sputtering chamber 300 includes a base (or “floor”) 320, a plurality of side walls 322, and a ceiling 330, together bounding the sputtering cavity 302. One or more upper targets 80 are mounted above the path of substrate travel 45, and one or more lower targets 180 are mounted below the path of substrate travel. In the illustrated embodiments, two upper targets 80 and two lower targets 180 are provided, although these details are merely optional.

The term “upper target” is used herein to refer to a target placed at a higher vertical position, e.g., a higher elevation, than the path of substrate travel. The upper target is not required to be positioned directly above the path of substrate travel, although this will commonly be the case. The term “lower target” is used herein to refer to a target placed at a lower vertical position, e.g., a lower elevation, than the path of substrate travel. The lower target is not required to be positioned directly below the path of substrate travel, although this will be the case in many embodiments.

In each of the illustrated chambers, the rollers are spaced apart along the path of substrate travel 45. In some cases, the rollers 50 are spaced substantially uniformly along a length (e.g., the entire length or substantially the entire length) of the chamber to define a continuous path of substrate travel extending through the chamber.

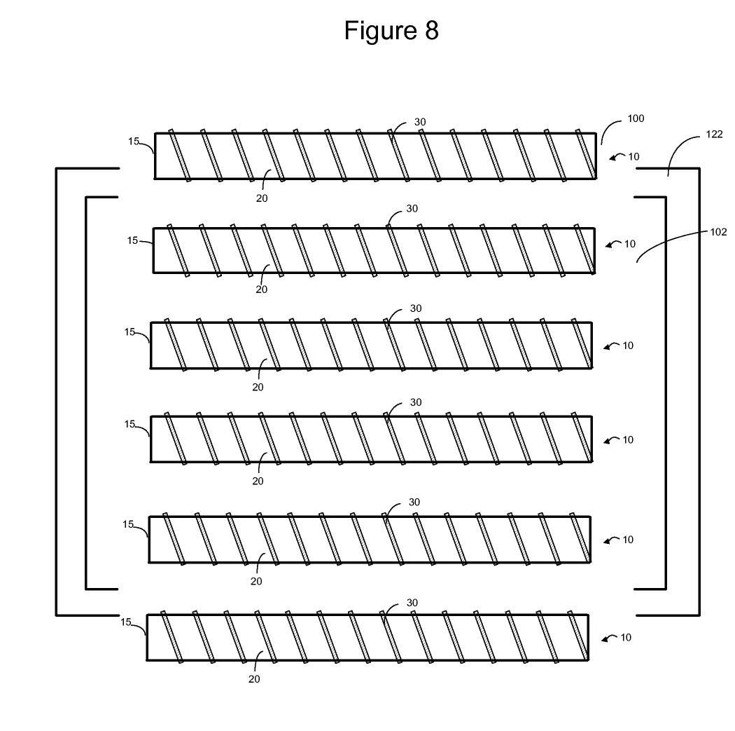

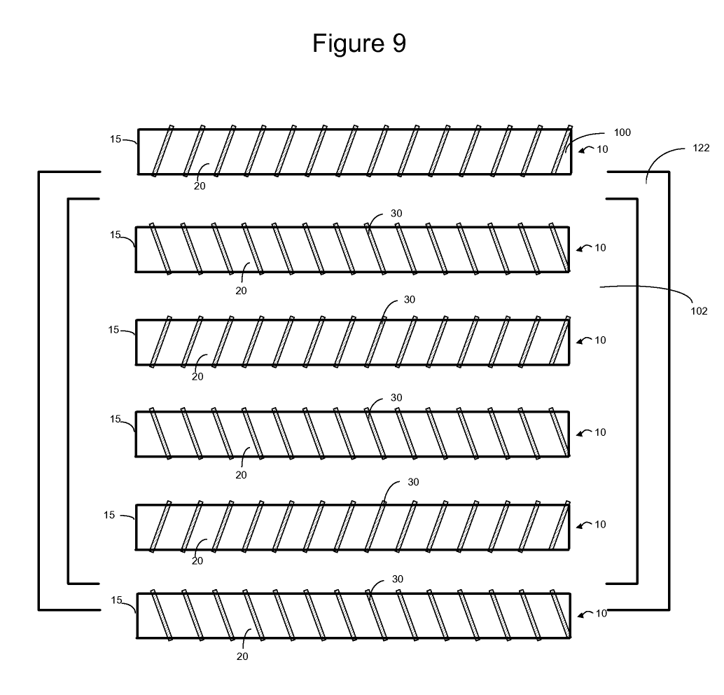

Each transport roller 10 preferably extends across at least half the width (and optionally across substantially the entire width) of the sputtering chamber, as exemplified in FIGS. 8 and 9. As noted above, each transport roller is optionally adapted to accommodate large-area substrates (e.g., substrates having a width of at least about 0.5 meter, optionally at least about 1 meter, perhaps more preferably at least about 1.5 meters, such as between about 2 meters and about 4 meters, and in some cases at least about 3 meters). In some embodiments, the length of each transport roller is within one or more of these ranges.

FIGS. 8 and 9 are schematic top views of a series of transport rollers mounted in a deposition chamber 100. The illustrated rollers are spaced apart at substantially uniform intervals within the cavity 102, although this is not required. In FIG. 8, the ropes 30 on all rollers 10 of the series are wound in a common direction. That is, all the ropes are wound about their respective rollers in a clockwise direction, or wound about their respective rollers in a counterclockwise direction. In FIG. 9, the respective ropes 30 on adjacent rollers 10 are wound in alternating directions. Thus, the rope on a first roller is wound around the first roller in a first direction (one of clockwise and counterclockwise), the rope on a second roller is wound around the second roller in a second direction (the other of clockwise and counterclockwise), the rope on a third roller is wound in the first direction, and so on. It can be particularly advantageous to wind the ropes in alternating directions, as this helps to keep the substrate properly aligned as it is conveyed over the rollers.

The invention also provides a method of conveying a substrate through a vacuum deposition chamber. The method includes providing a vacuum deposition chamber for applying thin films onto substrates. The chamber has a cavity in which a controlled (e.g., vacuous) environment can be established. The chamber includes at least one transport roller of the invention. Preferably, the chamber includes a plurality of transport rollers of the invention. The method involves transporting a substrate through the chamber by conveying the substrate over the transport rollers. The method may involve operating a motor attached to one or more of the rollers, so as to rotate one or more of the rollers, thereby conveying the substrate through the chamber along the path of substrate travel. In this method, each transport roller preferably comprises a cylindrical body having an outer surface defined by a thickness of nonstick material and a rope wound around the cylindrical body, such that the rope defines an elevated support that engages (i.e., comes in direct contact with) a bottom major surface of the substrate during conveyance.

What is claimed is:

1. A transport roller for conveying a large-area substrate, the roller comprising a cylindrical body having an outer surface defined by a thickness of nonstick material, wherein an elevated support is provided about the cylindrical body for engaging a bottom major surface of the large-area substrate.

2. The transport roller of claim 1 wherein the thickness of nonstick material is formed by a nonstick coating.

3. The transport roller of claim 2 wherein the nonstick coating comprises polytetrafluoroethylene.

4. The transport roller of claim 1 wherein the elevated support has an outer surface defined by a thickness of nonstick material.

5. The transport roller of claim 1 wherein the elevated support comprises a rope wound around the cylindrical body.

6. The transport roller of claim 5 wherein the wound rope has an outer surface defined by a thickness of nonstick material.

7. The transport roller of claim 6 wherein the nonstick material defining the outer surface of the rope comprises polytetrafluoroethylene.

8. The transport roller of claim 6 wherein the wound rope comprises a central core formed of a different material than the non-stick material defining the outer surface of the rope.

9. The transport roller of claim 8 wherein the central core of the rope includes an inner wire.

10. The transport roller of claim 9 wherein the inner wire is a metal wire.

11. The transport roller of claim 1 wherein the elevated support comprises a belt wound around at least part of the outer surface.

12. The transport roller of claim 1 wherein the belt is also wound around at least part of a guide roller.

13. The transport roller of claim 1 wherein the belt is also wound around at least part of another transport roller.

14. The transport roller of claim 1 wherein the cylindrical body comprises a hollow cylindrical tube.

15. The transport roller of claim 14 wherein the hollow cylindrical tube comprises aluminum.

16. The transport roller of claim 1 wherein the transport roller has a length of at least about 0.5 meter.

17. The transport roller of claim 16 wherein the transport roller has a length of at least about 1 meter.

18. The transport roller of claim 17 wherein the transport roller has a length of between about 2 meters and about 4 meters.

19. A vacuum deposition chamber for applying thin films onto a substrate, the chamber having a cavity in which a controlled environment can be established, the chamber including a series of transport rollers, at least one of the transport rollers comprising a cylindrical body having an outer surface defined by a thickness of nonstick material, wherein an elevated support is provided about the cylindrical body for engaging a bottom major surface of the substrate.

20. The vacuum deposition chamber of claim 19, wherein the chamber includes at least one sputtering target positioned in the cavity, the target being operatively connected to a power supply adapted to apply an electric charge to at least a portion of the target.

21. The vacuum deposition chamber of claim 19 wherein the chamber is an upward deposition chamber in which there is provided an upward coating apparatus adapted for coating the bottom major surface of the substrate when the substrate is conveyed through the chamber over the transport rollers.

22. The vacuum deposition chamber of claim 22 wherein the upward deposition chamber is an upward sputtering chamber and the upward coating apparatus comprises at least one lower sputtering target mounted in the cavity below the transport rollers.

23. The vacuum deposition chamber of claim 22 wherein the chamber is a dual-direction deposition chamber adapted for simultaneously coating the bottom major surface of the substrate and a top major surface of the substrate when the substrate is conveyed through the chamber over the transport rollers.

24. The vacuum deposition chamber of claim 23 wherein the dual-direction deposition chamber is a dual direction sputtering chamber, at least one upper sputtering target being mounted in the cavity above the transport rollers, and at least one lower sputtering target being mounted in the cavity below the transport rollers.

25. The vacuum deposition chamber of claim 19 wherein the transport rollers are spaced apart along a path of substrate travel extending through the cavity.

26. The vacuum deposition chamber of claim 19 wherein the elevated support has an outer surface defined by a thickness of nonstick material.

27. The vacuum deposition chamber of claim 19 wherein the elevated support comprises a rope wound around the cylindrical body.

28. The vacuum deposition chamber of claim 27 wherein the wound rope has an outer surface defined by a thickness of nonstick material.

29. The vacuum deposition chamber of claim 28 wherein the nonstick material defining the outer surface of the rope comprises polytetrafluoroethyene.

30. The vacuum deposition chamber of claim 28 wherein the wound rope comprises a central core formed of a different material than the non-stick material defining the outer surface of the rope.

31. The vacuum deposition chamber of claim 30 wherein the central core of the rope includes an inner wire.

32. The vacuum deposition chamber of claim 31 wherein the inner wire is a metal wire.

33. The vacuum deposition chamber of claim 19 wherein the elevated support comprises a belt wound around at least part of the outer surface.

34. The vacuum deposition chamber of claim 34 wherein the belt is also wound around at least part of a guide roller.

35. The vacuum deposition chamber of claim 34 wherein the belt is also wound around at least part of another transport roller.

36. The vacuum deposition chamber of claim 19 wherein the transport rollers are arranged so that the series of transport rollers each have ropes wound in alternating directions.

37. A method of conveying a substrate, the method comprising:
providing a vacuum deposition chamber for applying thin films onto the substrate, the chamber having a cavity in which a controlled environment can be established, the chamber including a series of transport rollers, at least one of the transport rollers comprising a cylindrical body having an outer surface defined by a thickness of nonstick material, wherein an elevated support is provided about the cylindrical body for engaging a bottom major surface of the substrate; and
transporting the substrate through the vacuum deposition chamber by conveying the substrate over the transport rollers such that the bottom major surface of the substrate comes into direct contact with the elevated support without directly contacting the outer surface of the cylindrical body.

38. The method of claim 37 wherein the elevated support has an outer surface defined by a thickness of nonstick material.

39. The method of claim 37 wherein the elevated support comprises a rope wound around the cylindrical body.

40. The method of claim 39 wherein the wound rope has an outer surface defined by a thickness of nonstick material.

41. The method of claim 40 wherein the nonstick material defining the outer surface of the rope comprises polytetrafluoroethylene.

42. The method of claim 40 wherein the bottom major surface of the substrate comes into direct contact with the nonstick material of the rope during the conveying the substrate over the transport rollers.

43. The method of claim 40 wherein the wound rope comprises a central core formed of a different material than the non-stick material defining the outer surface of the rope.

44. The method of claim 43 wherein the central core of the rope includes an inner wire.

45. The method of claim 44 wherein the inner wire is a metal wire.

46. The method of claim 37 wherein the elevated support comprises a belt wound around at least part of the outer surface.

47. The method of claim 37 wherein the belt is also wound around at least part of a guide roller.

48. The method of claim 37 wherein the belt is also wound around at least part of another transport roller.
